(19) United States
(12) Patent Application Publication
(10) Pub. No.: US 2026/0215223 A1
(43) Pub. Date: Jul. 23, 2026

(54) SUBSTRATE TREATING APPARATUS

(71) Applicant: SAMSUNG ELECTRONICS CO., LTD., Suwon-si (KR)

(72) Inventors: Jae Uk SIM, Suwon-si (KR); Kazuya ONO, Suwon-si (KR); Byeong Tak PARK, Suwon-si (KR); Kyung Bin BAE, Suwon-si (KR); Seung Hoo LEE, Suwon-si (KR); Un KIM, Suwon-si (KR); Si Woong WOO, Suwon-si (KR)

(73) Assignee: SAMSUNG ELECTRONICS CO., LTD., Suwon-si (KR)

(21) Appl. No.: 19/310,423

(22) Filed: Aug. 26, 2025

(30) Foreign Application Priority Data
Jan. 23, 2025 (KR) 10-2025-0010209

(51) Int. Cl. H01L 21/687; B32B 37/10; H01L 21/67

(52) U.S. Cl. CPC H10P 72/7624; B32B 37/1045; H10P 72/0438; B32B 2457/14

(57) ABSTRACT

A substrate treating apparatus including a deformation chuck capable of compensating for an asymmetric scale is provided. The substrate treating apparatus comprising: a first bonding chuck supporting a first substrate; and a second bonding chuck facing the first bonding chuck and supporting a second substrate, wherein the second bonding chuck includes a second stage fixing the second substrate, and the second stage is deformed based on a moment applied along an edge region thereof.

### CROSS-REFERENCE TO RELATED APPLICATION

This application claims priority from Korean Patent Application No. 10-2025-0010209 filed on Jan. 23, 2025 in the Korean Intellectual Property Office and all the benefits accruing therefrom under 35 U.S.C. 119, the contents of which in its entirety are herein incorporated by reference.

### BACKGROUND

### 1. Technical Field

The present disclosure relates to a substrate treating apparatus for treating a substrate in a semiconductor manufacturing plant.

### 2. Description of the Related Art

When a memory semiconductor is manufactured, a cell wafer and a peri wafer may be bonded to each other, so that the memory semiconductor may be manufactured in a cell on peri (COP) structure. However, warpage of the cell wafer may occur in XY direction differently, whereby a pattern may have different scales in the XY direction. Therefore, when two wafers are bonded to each other by a symmetrical bonding method, bonding misalignment between the two wafers may occur, and the yield of the semiconductor may be deteriorated.

### BRIEF SUMMARY

An object of the present disclosure is to provide a substrate treating apparatus including a deformation chuck capable of compensating for an asymmetric scale.

The objects of the present disclosure are not limited to those mentioned above and additional objects of the present disclosure, which are not mentioned herein, will be clearly understood by those skilled in the art from the following description of the present disclosure.

According to an aspect of the present disclosure, a substrate treating apparatus comprising: a first bonding chuck supporting a first substrate; and a second bonding chuck facing the first bonding chuck and supporting a second substrate, wherein the second bonding chuck includes a second stage fixing the second substrate, and the second stage is deformed based on a moment applied along an edge region thereof.

According to another aspect of the present disclosure, a substrate treating apparatus comprising: a first bonding chuck supporting a first substrate; and a second bonding chuck facing the first bonding chuck and supporting the second substrate, wherein the second bonding chuck includes: a second stage fixing the second substrate; a plurality of moment levers coupled to the second stage along an edge region of the second stage; and a plurality of flexures individually coupled to the moment levers, wherein the edge region of the second stage includes a plurality of portions, and the second stage is symmetrically deformed based on a certain moment applied along each portion.

According to another aspect of the present disclosure, a substrate treating apparatus comprising: a first bonding chuck supporting a first substrate; and a second bonding chuck facing the first bonding chuck and supporting a second substrate, wherein the second bonding chuck includes: a second stage fixing the second substrate; a plurality of moment levers coupled to the second stage along an edge region of the second stage; and a plurality of flexures individually coupled to the moment levers, wherein the edge region of the second stage includes a plurality of portions, and the second stage is asymmetrically deformed based on a pattern scale formed in the second substrate or a moment differentially applied depending on warpage generated in the second substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a first exemplary view illustrating an internal structure of a semiconductor manufacturing facility including a substrate treating apparatus according to some embodiments of the present disclosure.

FIG. 2 is a second exemplary view illustrating an internal structure of a semiconductor manufacturing facility including a substrate treating apparatus according to some embodiments of the present disclosure.

FIG. 3 is a third exemplary view illustrating an internal structure of a semiconductor manufacturing facility including a substrate treating apparatus according to some embodiments of the present disclosure.

FIG. 4 is a fourth exemplary view illustrating an internal structure of a semiconductor manufacturing facility including a substrate treating apparatus according to some embodiments of the present disclosure.

FIG. 5 is an exemplary view illustrating an internal structure of a substrate treating apparatus according to some embodiments of the present disclosure.

FIG. 6 is an exemplary view illustrating an operation method of a substrate treating apparatus according to some embodiments of the present disclosure.

FIG. 7 is an exemplary view illustrating a force-based bending mechanism.

FIG. 8 is a first exemplary view illustrating a moment bending mechanism according to some embodiments of the present disclosure.

FIG. 9 is a second exemplary view illustrating a moment bending mechanism according to some embodiments of the present disclosure.

FIG. 10 is a first exemplary view illustrating a structure of a second stage constituting a second bonding chuck according to some embodiments of the present disclosure.

FIG. 11 is a second exemplary view illustrating a structure of a second stage constituting a second bonding chuck according to some embodiments of the present disclosure.

FIG. 12 is a first exemplary view illustrating a moment applied to a second stage according to some embodiments of the present disclosure.

FIG. 13 is a second exemplary view illustrating a moment applied to a second stage according to some embodiments of the present disclosure.

FIG. 14 is a third exemplary view illustrating a moment applied to a second stage according to some embodiments of the present disclosure.

FIG. 15 is a fourth exemplary view illustrating a moment applied to a second stage according to some embodiments of the present disclosure.

FIG. 16 is a third exemplary view illustrating a structure of a second stage constituting a second bonding chuck according to some embodiments of the present disclosure.

FIG. 17 is a fifth exemplary view illustrating a moment applied to a second stage according to some embodiments of the present disclosure.

FIG. 18 is a sixth exemplary view illustrating a moment applied to a second stage according to some embodiments of the present disclosure.

FIG. 19 is a first exemplary view illustrating a verification result of a moment bending mechanism according to some embodiments of the present disclosure.

FIG. 20 is a second exemplary view illustrating a verification result of a moment bending mechanism according to some embodiments of the present disclosure.

FIG. 21 is a fourth exemplary view illustrating a structure of a second stage constituting a second bonding chuck according to some embodiments of the present disclosure.

FIG. 22 is a seventh exemplary view illustrating a moment applied to a second stage according to some embodiments of the present disclosure.

FIG. 23 is an eighth exemplary view illustrating a moment applied to a second stage according to some embodiments of the present disclosure.

### DETAILED DESCRIPTION OF THE DISCLOSURE

Embodiments of the present disclosure will hereinafter be described with reference to the accompanying drawings. The same reference numerals are used for identical components in the drawings, and redundant explanations for these components are omitted.

First, a semiconductor manufacturing facility including a substrate treating apparatus will be described, and then the substrate treating apparatus will be described in detail.

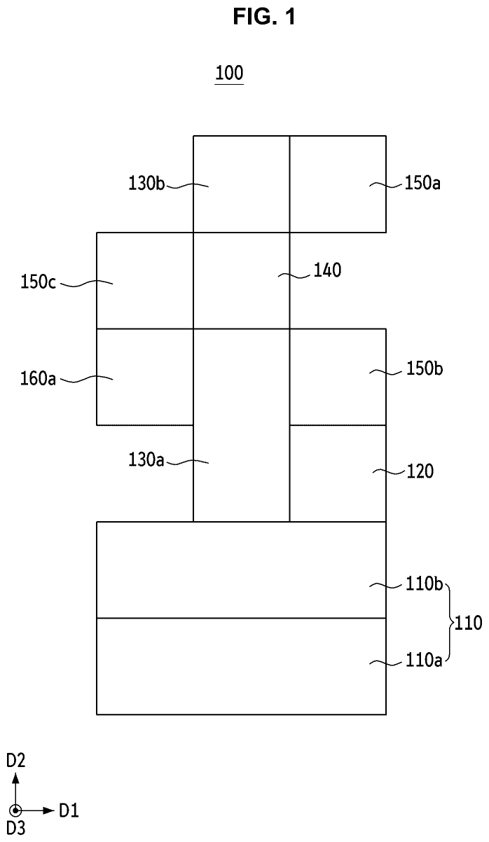

FIG. 1 is a first exemplary view illustrating an internal structure of a semiconductor manufacturing facility including a substrate treating apparatus according to some embodiments of the present disclosure. Referring to FIG. 1, a semiconductor manufacturing facility 100 may include a load port module 110a, an index module 110b, a buffer chamber 120, a first transfer module 130a, a second transfer module 130b, a load lock chamber 140, a first process chamber 150a, a second process chamber 150b, and a third process chamber 150c.

A first direction D1 and a second direction D2 may constitute a two-dimensional plane. The first direction D1 may be an X-axis direction, and the second direction D2 may be a Y-axis direction. The first direction D1 may be a left-right direction, and the second direction D2 may be a front-rear direction. Alternatively, the first direction D1 may be a front-rear direction, and the second direction D2 may be a left-right direction. A third direction D3 may constitute a three-dimensional body with the first and second directions D1 and D2. The third direction D3 is a direction perpendicular to a plane constituted by the first and second directions D1 and D2. The third direction D3 may be a Z-axis direction. The third direction D3 may be an up and down direction.

The semiconductor manufacturing facility 100 may plasma-treat each of first and second substrates. The semiconductor manufacturing facility 100 may perform a cleaning treatment for each of the first and second substrates after plasma-treating the first and second substrates. The semiconductor manufacturing facility 100 may bond the first and second substrates to each other after cleaning the first and second substrates. The semiconductor manufacturing facility 100 may be provided as a wafer bonding facility.

The load port module 110a may provide a seating surface to a container. The container may be delivered to the load port module 110a by a ceiling transfer device or a ground transfer device. The container may accommodate a plurality of substrates. For example, the container may be provided as a front opening unified pod (FOUP). The ceiling transfer device may carry the container while moving from the ceiling of the semiconductor manufacturing plant. For example, the ceiling transfer device may be provided as an overhead hoist transport (OHT). The ground transfer device may carry the container while moving on the ground of the semiconductor manufacturing plant. For example, the ground transfer device may be provided as an autonomous mobile robot (AMR) or an automatic guided vehicle (AGV). In the load port module 110a, the container may be loaded or unloaded. In the load port module 110a, the substrate accommodated in the container may be loaded or unloaded.

A plurality of containers may be seated on the load port module 110a. Each container may load the same kind of goods. For example, a first container, a second container and a third container may load wafers. Each container may load different kinds of goods. For example, the first container may load a wafer, the second container may load a reticle, and the third container may load consumable parts such as a focus ring, but the present disclosure is not limited thereto. Some of the plurality of containers may load the same kind of goods, and some other containers may load different kinds of goods.

The index module 110b may be arranged behind the load port module 110a. The index module 110b may be provided as an interface so that the substrate may be carried in and out between the load port module 110a and the buffer chamber 120. Although not shown in FIG. 1, the index module 110b may include a first transfer robot for carrying in and out the substrate. The first transfer robot may carry in and out the substrate under an atmospheric pressure environment. The load port module 110a and the index module 110b may constitute an equipment front end module (EFEM) 110.

The buffer chamber 120 may temporarily store the substrate. The buffer chamber 120 may store an untreated substrate before transferring the same to the load lock chamber 140. The buffer chamber 120 may store a pre-treated substrate before transferring the same to the container on the load port module 110a. The buffer chamber 120 may be arranged behind the index module 110b. The first transfer robot may carry the substrate into and out of the buffer chamber 120.

The first transfer module 130a may be provided as an interface for carrying in and out the substrate between the buffer chamber 120 and the load lock chamber 140. The first transfer module 130a may be provided as an interface for carrying in and out the substrate between the load lock chamber 140 and the second process chamber 150b. The first transfer module 130a may be provided as an interface for carrying in and out the substrate between the second process chamber 150b and the third process chamber 150c. The first transfer module 130a may be surrounded by the buffer chamber 120, the load lock chamber 140, the second process chamber 150b, and the third process chamber 150c.

The first transfer module 130a may include a second transfer robot for carrying in and out the substrate. The second transfer robot may carry the substrate in and out of the buffer chamber 120. The second transfer robot may carry the substrate in and out of the load lock chamber 140. The second transfer robot may carry the substrate in and out of the second process chamber 150b. The second transfer robot may carry the substrate in and out of the third process chamber 150c. The second transfer robot may carry in and out the substrate in an atmospheric pressure environment. The first transfer robot and the second transfer robot may carry in and out the substrate in the same environment.

The load lock chamber 140 may temporarily store the substrate. The load lock chamber 140 may store the untreated substrate and the pre-treated substrate between the first transfer module 130a and the second transfer module 130b. Although not shown in FIG. 1, the load lock chamber 140 may include a buffer stage for storing the substrate.

The buffer stage may be provided as a plurality of buffer stages in the load lock chamber 140. For example, a first buffer stage and a second buffer stage may be provided in the load lock chamber 140. The first buffer stage may store the untreated substrate, and the second buffer stage may store the pre-treated substrate, but the present disclosure is not limited thereto. The first buffer stage and the second buffer stage may store the substrate regardless of whether or not the substrate is treated. The first buffer stage and the second buffer stage may store a single substrate, but may also store a plurality of substrates.

The second transfer module 130b may be provided as an interface for carrying in and out the substrate between the load lock chamber 140 and the first process chamber 150a. The second transfer module 130b may include a third transfer robot for carrying in and out the substrate. The third transfer robot may carry in and out the substrate in a vacuum environment. The third transfer robot may carry in and out the substrate in an environment different from the first and second transfer robots.

The first process chamber 150a may plasma-treat the substrate. The first process chamber 150a may form a dangling bond on a surface of the substrate. First, when the process gas is supplied to the inside of the chamber and then is excited under a vacuum atmosphere, the process gas may be plasmaized to produce ions and active species. Afterwards, when the ions and the active species are irradiated onto the surface of the substrate, the surface of the substrate may be modified to form the dangling bond.

The first process chamber 150a may treat the substrate by using an inductively coupled plasma (ICP) source, but the present disclosure is not limited thereto. The first process chamber 150a may treat the substrate by using a capacitively coupled plasma (CCP) source. Alternatively, the first process chamber 150a may treat the substrate by using a microwave plasma source.

The second process chamber 150b may operate subsequently to the first process chamber 150a. The second process chamber 150b may subsequently treat the substrate treated by the first process chamber 150a. The second process chamber 150b may clean the substrate. The second process chamber 150b may treat the substrate by a wet cleaning method. The second process chamber 150b may treat the substrate by using a chemical solution, ultrapure water (DIW), etc. The second process chamber 150b may not only clean the surface of the substrate but also allow-OH groups, water molecules, etc. to be well bonded to the surface of the substrate, thereby facilitating bonding between the first substrate and the second substrate.

The third process chamber 150c may bond the first substrate and the second substrate to each other. The first substrate and the second substrate may be plasma-treated and cleaned in the first process chamber 150a and the second process chamber 150b, respectively, and then may move to the third process chamber 150c. For example, the first substrate may be provided as a substrate on which circuits for image sensor chips are formed, and the second substrate may be provided as a substrate on which light receiving sensors for image sensor chips are formed. Alternatively, the first substrate may be provided as a substrate on which circuits for a semiconductor package are formed, and the second substrate may be provided as a substrate on which memories for a semiconductor package are formed. Alternatively, the first substrate may be provided as a peri wafer, and the second substrate may be provided as a cell wafer. A more detailed description of the third process chamber 150c will be described later.

The semiconductor manufacturing facility 100 may further include a first inspection device 160a. The first inspection device 160a may inspect the substrate. The first inspection device 160a may inspect whether particles are present on the substrate. For example, the first inspection device 160a may inspect whether particles or contaminants are present on the substrate. The first inspection device 160a may inspect both surfaces of the substrate, but the present disclosure is not limited thereto. The first inspection device 160a may inspect only one surface of the substrate. When the first inspection device 160a inspects only one surface of the substrate, the first inspection device 160a may inspect a bonding surface of the substrate.

The first inspection device 160a may inspect the first and second substrates. The first inspection device 160a may inspect the first and second substrates before bonding the first and second substrates to each other. The first inspection device 160a may be provided on a path along which the first and second substrates move to the third process chamber 150c. The first inspection device 160a may be arranged between the first transfer module 130a and the third process chamber 150c. The first inspection device 160a may not be provided in the semiconductor manufacturing facility 100.

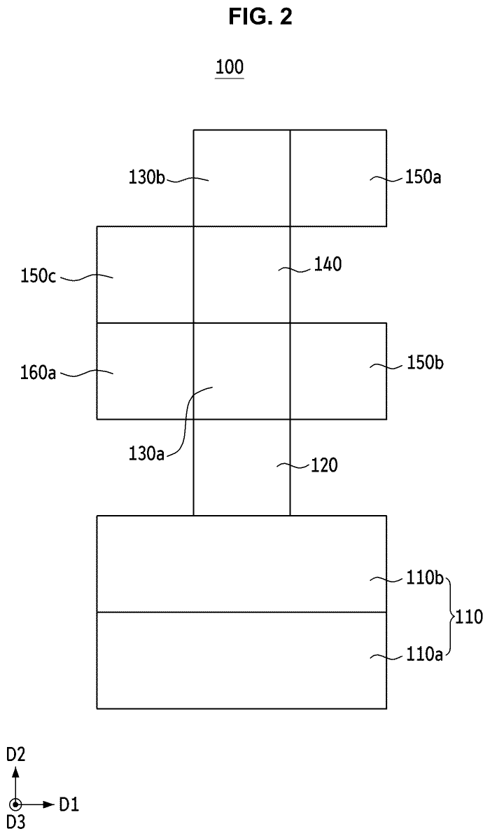

FIG. 2 is a second exemplary view illustrating an internal structure of a semiconductor manufacturing facility including a substrate treating apparatus according to some embodiments of the present disclosure. Hereinafter, description of redundant portions as compared with FIG. 1 will be omitted, and only portions different from those of FIG. 1 will be described.

The buffer chamber 120 may be adjacent to the index module 110b. Also, the buffer chamber 120 may be adjacent to the first transfer module 130a. In case of FIG. 1, the first transfer module 130a may be also adjacent to the index module 110b. The buffer chamber 120 may be arranged behind the index module 110b, and may be arranged at a side of the first transfer module 130a. In contrast, in case of FIG. 2, the first transfer module 130a may be spaced apart from the index module 110b. The buffer chamber 120 is arranged between the index module 110b and the first transfer module 130a, and the index module 110b and the first transfer module 130a may be spaced apart from each other by the buffer chamber 120.

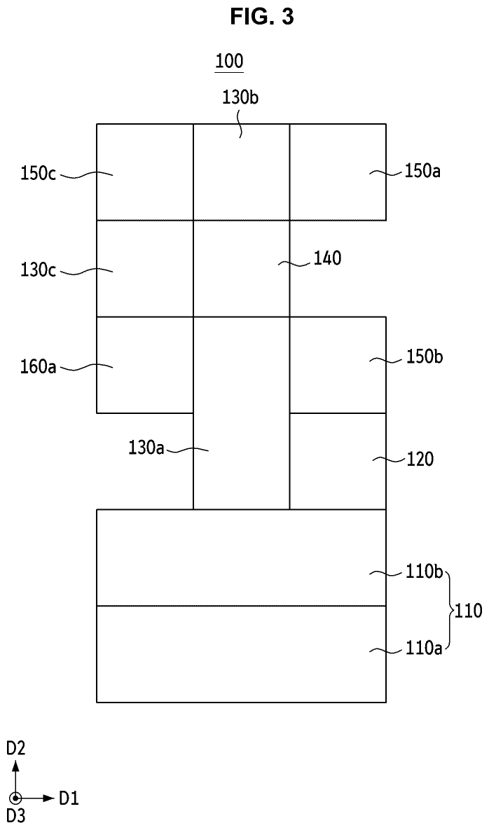

FIG. 3 is a third exemplary view illustrating an internal structure of a semiconductor manufacturing facility including a substrate treating apparatus according to some embodiments of the present disclosure. Hereinafter, description of redundant portions as compared with FIG. 1 will be omitted, and only portions different from those of FIG. 1 will be described.

The semiconductor manufacturing facility 100 may further include a third transfer module 130c. The third transfer module 130c may be provided as an interface for carrying in and out the substrate between the first transfer module 130a and the third process chamber 150c. The third transfer module 130c may include a fourth transfer robot for carrying in and out the substrate. The fourth transfer robot may carry in and out the substrate in the atmospheric pressure environment. The fourth transfer robot may carry in and out the substrate in the same environment as the first and second transfer robots. The fourth transfer robot may carry in and out the substrate in a different environment from the third transfer robot.

The fourth transfer robot may flip the substrate. The fourth transfer robot may include a cooling plate. The cooling plate may cool the first and second substrates before the first and second substrates are bonded to each other. When the semiconductor manufacturing facility 100 does not include the third transfer module 130c, the second transfer robot may include a cooling plate.

A plurality of transfer robots may be provided in the third transfer module 130c. For example, the third transfer module 130c may include a first substrate robot and a second substrate robot. The first substrate robot and the second substrate robot may carry a designated substrate into the third process chamber 150c. For example, the first substrate robot may carry in the first substrate, and the second substrate robot may carry in the second substrate, but the present disclosure is not limited thereto. The first substrate robot and the second substrate robot may carry an undesignated substrate into the third process chamber 150c. For example, the first substrate robot may carry in the substrate, which is provided in advance, of the first substrate and the second substrate, and the second substrate robot may carry in the substrate, which is provided subsequently, of the first substrate and the second substrate.

The example of FIG. 3 may be equally applied to the example of FIG. 2 as well as the example of FIG. 1.

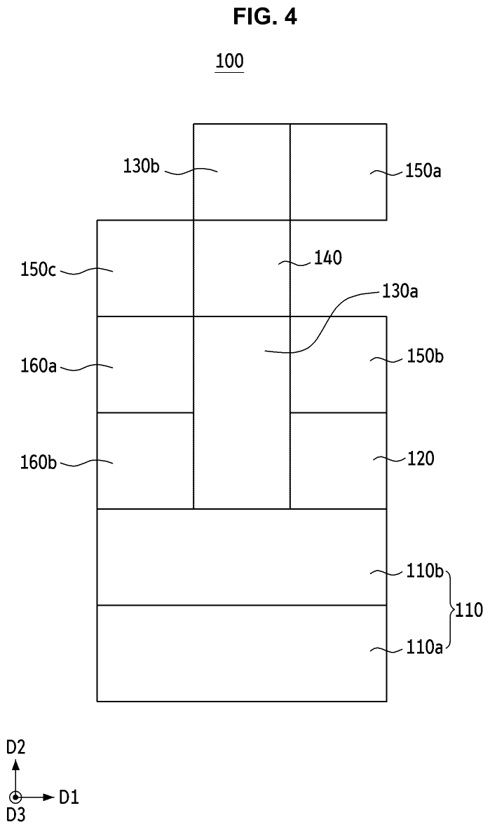

FIG. 4 is a fourth exemplary view illustrating an internal structure of a semiconductor manufacturing facility including a substrate treating apparatus according to some embodiments of the present disclosure. Hereinafter, description of redundant portions as compared with FIG. 1 will be omitted, and only portions different from those of FIG. 1 will be described.

The semiconductor manufacturing facility 100 may further include a second inspection device 160b. The second inspection device 160b may inspect the substrate. When the first substrate and the second substrate are bonded to each other by the third process chamber 150c, the second inspection device 160b may inspect the bonded substrate. The second inspection device 160b may inspect whether the bonding state between the first substrate and the second substrate is good.

The second inspection device 160b may be arranged adjacent to the first transfer module 130a. The second transfer robot may provide the substrate bonded by the third process chamber 150c to the second inspection device 160b.

The example of FIG. 4 may be applied equally to the example of FIG. 2 as well as the example of FIG. 1. Alternatively, the example of FIG. 4 may be applied equally to the example of FIG. 3. Although not shown in FIGS. 1 to 3, the example of FIG. 4 may be applied equally to the example in which the third transfer module 130c is reflected based on the example of FIG. 2.

Although not shown in FIGS. 1 to 4, the semiconductor manufacturing facility 100 may further include a control device. The control device may include a processor for controlling each component of the semiconductor manufacturing facility 100, a network for performing wired or wireless communication with each component, one or more instructions related to a function or operation for controlling each component, processing recipes including instructions, and a storage means for storing various data. The control device may further include a user interface that includes an input means for performing a command input operation or the like by an operator to manage the semiconductor manufacturing facility 100 and an output means for visually displaying an operational status of the semiconductor manufacturing facility 100. The control device may be provided as a computing device for data processing and analysis, command transmission, etc.

The instruction may be provided in the form of a computer program or an application. The computer program may include one or more instructions and be stored on a computer-readable recording medium. The instruction may include code generated by a compiler, code executed by an interpreter, and the like. The storage means may be provided as one or more storage media selected from a flash memory, an HDD, an SSD, a card-type memory, a RAM, an SRAM, a ROM, an EEPROM, a PROM, a magnetic memory, a magnetic disk, and an optical disk.

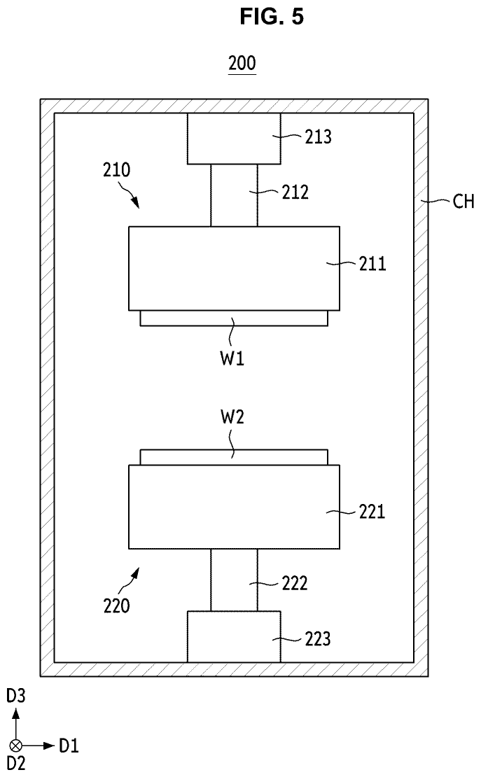

Next, the third process chamber 150c will be described. Hereinafter, the third process chamber 150c will be defined as a substrate treating apparatus. FIG. 5 is an exemplary view illustrating an internal structure of a substrate treating apparatus according to some embodiments of the present disclosure. Referring to FIG. 5, a substrate treating apparatus 200 may include a chamber housing CH, a first bonding chuck 210, and a second bonding chuck 220.

The chamber housing CH may provide a space, in which bonding may be performed for a first substrate W1 and a second substrate W2, and an environment thereof. The chamber housing CH may accommodate the first bonding chuck 210 and the second bonding chuck 220. The first bonding chuck 210 and the second bonding chuck 220 may be arranged to face each other in the third direction D3.

The first bonding chuck 210 may support one of the first substrate W1 and the second substrate W2. The second bonding chuck 220 may support the other one of the first substrate W1 and the second substrate W2. The following description will be based on that the first bonding chuck 210 supports the first substrate W1 and the second bonding chuck 220 supports the second substrate W2, but the present embodiment is not necessarily limited thereto.

The first bonding chuck 210 may include a first stage 211, a first support shaft 212, and a first driving unit 213. The first stage 211 may adsorb and fix the first substrate W1 through the first stage. The first support shaft 212 and the first driving unit 213 may be coupled to the first stage 211. The first driving unit 213 may provide a driving force to the first support shaft 212. The first support shaft 212 may elevate the first stage 211 under the control of the first driving unit 213. The first stage 211 may approach the second bonding chuck 220, or may move away from the second bonding chuck 220. A height of the first stage 211 may be adjusted by the first support shaft 212 and the first driving unit 213.

The first bonding chuck 210 may fix the first substrate W1 through an external force by a vacuum pressure, an electrostatic force or Bernoulli's Theorem. The first bonding chuck 210 may include an external force generator. When the vacuum pressure is used, the first bonding chuck 210 may fix the first substrate W1 through a plurality of vacuum grooves. The plurality of vacuum grooves may be formed in a portion of the first stage 211 on which the first substrate W1 is seated. The external force generator may be provided as a vacuum pump that applies the vacuum pressure to the plurality of vacuum grooves. When the vacuum pressure is formed in the plurality of vacuum grooves by the external force generator, the first substrate W1 may be fixed to the first bonding chuck 210.

When the electrostatic force is used, the first bonding chuck 210 may fix the first substrate W1 through a plurality of electrodes. The plurality of electrodes may be located in a portion of the first stage 211 on which the first substrate W1 is seated. The external force generator may be provided as a power source for forming the electrostatic force in the plurality of electrodes. When then electrostatic force is generated in the plurality of electrodes by the external force generator, the first substrate W1 may be fixed to the first bonding chuck 210.

When the Bernoulli's Theorem is used, the first bonding chuck 210 may fix the first substrate W through a plurality of holes. The plurality of holes may be formed in a portion of the first stage 211 on which the first substrate W1 is seated, and may discharge or suck a fluid. The external force generator may be provided as a pump that provides the fluid to the plurality of holes or sucks the fluid from the plurality of holes. According to the Bernoulli's Theorem, a region in which the fluid moves relatively quickly compared to surrounding regions has a pressure relatively lower than the surrounding regions. That is, a relatively low pressure may be formed between the first substrate W1 and the first bonding chuck 210 by a relatively high speed of the air formed through the plurality of holes. The first substrate W1 may be fixed to the first bonding chuck 210 by the low pressure formed between the first substrate W1 and the first bonding chuck 210.

The second bonding chuck 220 may include a second stage 221, a second support shaft 222, and a second driving unit 223. The second stage 221 may adsorb and fix the second substrate W2 through the second stage. The second support shaft 222 and the second driving unit 223 may be coupled to the second stage 221. The second driving unit 223 may provide a driving force to the second support shaft 222. The second support shaft 222 may elevate the second stage 221 under control of the second driving unit 223. The second stage 221 may approach the first bonding chuck 210, or may move away from the first bonding chuck 210. A height of the second stage 221 may be adjusted by the second support shaft 222 and the second driving unit 223.

The second bonding chuck 220, like the first bonding chuck 210, may fix the second substrate W2 through an external force by a vacuum pressure, an electrostatic force or Bernoulli's Theorem.

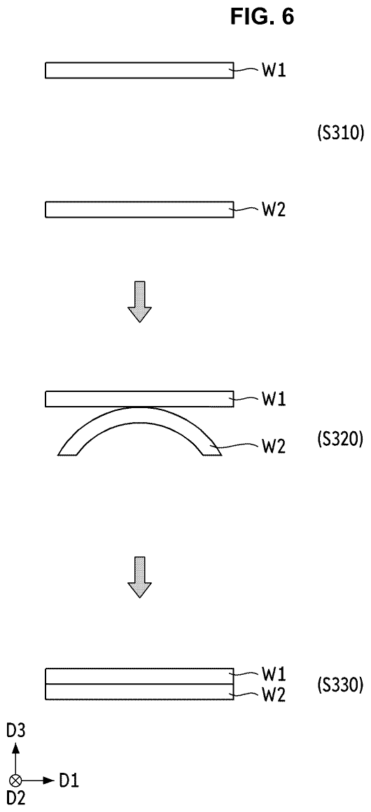

FIG. 6 is an exemplary view illustrating an operation method of a substrate treating apparatus according to some embodiments of the present disclosure. First, referring to step S310, the first bonding chuck 210 may support the first substrate W1, and the second bonding chuck 220 may support the second substrate W2. The first bonding chuck 210 and the second bonding chuck 220 may be spaced apart from each other. The first substrate W1 and the second substrate W2 may be arranged to face each other in the third direction D3, and may be spaced apart from each other.

Subsequently, referring to step S320, the first bonding chuck 210 may descend in a direction in which the second bonding chuck 220 is located. When the first bonding chuck 210 descends, the first substrate W1 may meet the second substrate W2. The first substrate W1 may not be bent, and the second substrate W2 may be curved to be convex upward, but the present disclosure is not limited thereto. The first substrate W1 may be curved to be convex downward, and the second substrate W2 may not be bent. Alternatively, both the first substrate W1 and the second substrate W2 may be curved to be convex. The first substrate W1 may be in contact with the second substrate W2 on a portion of a surface thereof.

Alternatively, the second bonding chuck 220 may ascend in a direction in which the first bonding chuck 210 is located. When the second bonding chuck 220 ascends, the second substrate W2 may meet the first substrate W1. At least one of the first substrate W1 or the second substrate W2 may be in a curved state, and the second substrate W2 may be in contact with the first substrate W1 on a portion of a surface thereof.

Alternatively, the first bonding chuck 210 may descend in a direction in which the second bonding chuck 220 is located, and the second bonding chuck 220 may ascend in a direction in which the first bonding chuck 210 is located. When the first bonding chuck 210 descends and the second bonding chuck 220 ascends, the first substrate W1 and the second substrate W2 may meet. At least one of the first substrate W1 or the second substrate W2 may be in a curved state, and the first substrate W1 and the second substrate W2 may be in contact with each other on a portion of surfaces thereof.

Subsequently, referring to step S330, in a state that the second substrate W2 is deformed to be convex upward, a central portion of the first substrate W1 may be first in contact with the second substrate W2, and then the other portion of the first substrate W1 may be gradually in contact with the second substrate W2 in an outward direction. An entire surface of the first substrate W1 may be in contact with the second substrate W2, and the first substrate W1 and the second substrate W2 may be bonded to each other.

The substrate treating apparatus 200 may be used to manufacture a memory semiconductor in a Cell On Peri (COP) structure. For example, the first substrate W1 may be provided as a peri wafer, and the second substrate W2 may be provided as a cell wafer. In the substrate treating apparatus 200, when the peri wafer and the cell wafer are separately manufactured on the first substrate W1 and the second substrate W2, the first substrate W1 and the second substrate W2 may be bonded to each other through wafer bonding and connected as one device. When a peri manufacturing process and a cell manufacturing process are separated by individual substrates, transistors of the peri wafer are not exposed to a high temperature and high pressure environment required for cell manufacture, and thus may not be contaminated and may operate at a high speed. When the peri manufacturing process and the cell manufacturing process are separated by individual substrates, a limitation due to a difference in heat budget between the peri wafer and the cell wafer may be overcome.

When the peri wafer and the cell wafer are subjected to wafer to wafer bonding, it is necessary to perform bonding with a minimum misalignment with respect to two substrates that are completely different from each other in warpage and pattern scale. In case of the cell wafer (i.e., the second substrate W2), warpage may occur severely only in a specific direction due to a cut process of a word line formed only in the specific direction on the substrate. In addition, in a process in which warpage occurs differently in the XY direction (i.e., the first direction D1 and the second direction D2), the pattern of the surface of the substrate may also have different scales in the XY direction. As a result, a copper pad (Cu Pad) of the bonding surface may be formed at different scales in the XY direction. In this case, the scale refers to a bonding characteristic by relative expansion/contraction between two wafers among bonding errors after the bonding is completed.

On the other hand, since the peri wafer (i.e., the first substrate W1) does not have the above characteristics, a copper pad may be formed at the same scale without XY directionality. When symmetric bonding is performed for two substrates having different pattern scale tendencies, the difference in pattern scale may be transferred as bonding misalignment as it is. Accordingly, the substrate treating apparatus 200 needs to compensate for the asymmetric scale to bond the first substrate W1 and the second substrate W2 to each other.

The present disclosure provides a wafer chuck and a moment bending mechanism for deforming the wafer chuck. The wafer chuck may compensate not only for a scale of a symmetrical shape in the wafer bonding but also for a scale of an asymmetric shape between XY. The wafer chuck may be provided as a deformation wafer chuck based on the moment bending mechanism. The wafer chuck may be provided in the first bonding chuck 210. The wafer chuck may be provided to the first stage 211. The wafer chuck may be provided in the second bonding chuck 220. The wafer chuck may be provided to the second stage 221. The wafer chuck may be applied to any one of the first bonding chuck 210 and the second bonding chuck 220, but may also be applied to both the first bonding chuck 210 and the second bonding chuck 220.

The moment bending mechanism may include a moment lever mechanism and a wedge mechanism. The moment lever mechanism and the wedge mechanism will be described later. The substrate treating apparatus 200 may deform the first substrate W1 and/or the second substrate W2 in accordance with a shape of a quadratic curve through the wafer chuck and the moment bending mechanism, and may cause uniform scale deformation on the entire surface of the first substrate W1 and/or the second substrate W2. The substrate treating apparatus 200 may apply XY moment differently through the wafer chuck and the moment bending mechanism, and may compensate for the asymmetric scale between XY.

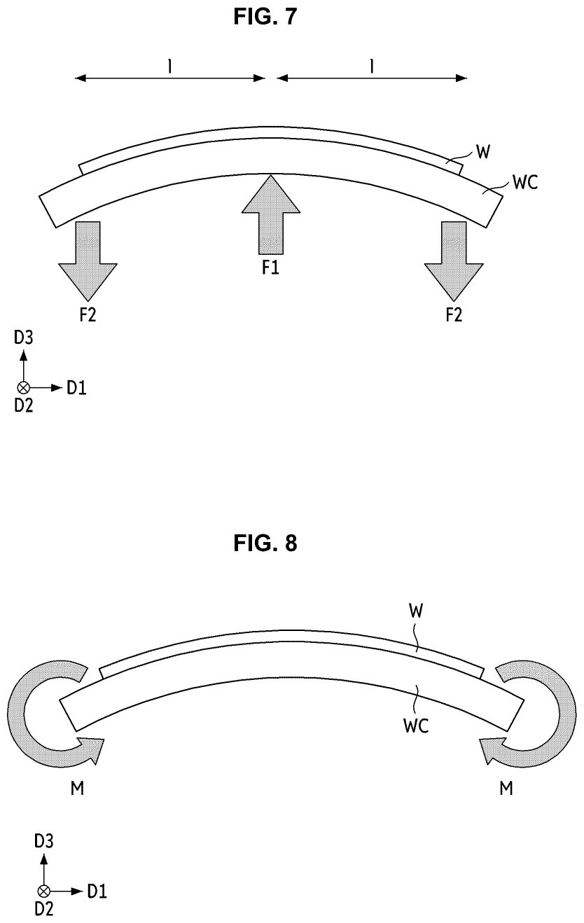

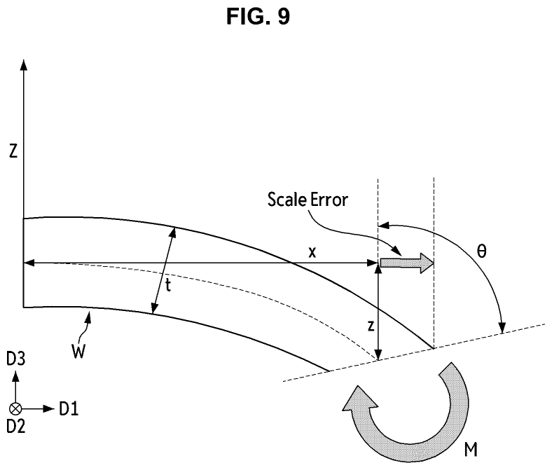

The moment bending mechanism may deform the wafer chuck by applying a moment to an end of the wafer chuck. The moment bending mechanism may have the following differentiation from a force-based bending mechanism in which a force is applied from a lower portion of the chuck to lift the chuck in a vertical direction. FIG. 7 is an exemplary view illustrating a force-based bending mechanism. FIG. 8 is a first exemplary view illustrating a moment bending mechanism according to some embodiments of the present disclosure. FIG. 9 is a second exemplary view illustrating a moment bending mechanism according to some embodiments of the present disclosure.

Referring to FIG. 7, in the force-based bending mechanism, a force may be applied to a lower portion of the wafer chuck WC. A force F1 for pushing the wafer chuck WC may be applied to the lower portion of the wafer chuck WC. A force F2 for pulling the wafer chuck WC may be applied to the lower portion of the wafer chuck WC. Any one of the force F1 for pushing the wafer chuck WC and the force F2 for pulling the wafer chuck WC may be applied to the lower portion of the wafer chuck WC, but the present disclosure is not limited thereto, and both the force F1 for pushing the wafer chuck WC and the force F2 for pulling the wafer chuck WC may be applied to the lower portion of the wafer chuck WC. When both the force F1 for pushing the wafer chuck WC and the force F2 for pulling the wafer chuck WC are applied, magnitudes of the two forces F1 and F2 may be equal. In bending by a force, a shape proportional to a third term of a radial position x of the substrate W may be formed on each of the wafer chuck WC and the substrate W. When bending by a force is expressed as an equation, the corresponding equation 1 may be as follows.

$$Z = \frac{F}{6 EI} ( {x}^{3} - 3 {lx}^{2} ) \qquad [ Equation 1 ]$$

In the above equation, Z denotes a displacement of the substrate W in the third direction D3. F denotes a magnitude of a force acting on the wafer chuck WC. E denotes an elastic modulus. For example, E may be provided as Young's modulus. I denotes a moment of inertia. x denotes a radius of the substrate W.

On the other hand, referring to FIG. 8, the moment bending mechanism may generate a moment M at each end of the wafer chuck WC. The moment M may act in the third direction D3. In bending by the moment, a shape proportional to a secondary term of a radial position x of the substrate W may be formed in the wafer chuck WC and the substrate W, respectively. When bending by the moment is expressed as an equation, the corresponding equation 2 may be as follows.

$$Z = - \frac{{Mx}^{2}}{2 EI} \qquad [ Equation 2 ]$$

In the above, M denotes a moment at a position x.

Referring to FIG. 9, when a shape (secondary Deform Shape) proportional to a quadratic curve of x is formed in the wafer chuck WC and the substrate W, respectively, a radial displacement (scale error) at a radial position x of the substrate W is proportional to x, and deformation corresponding to the definition of the scale may be induced. According to the moment bending mechanism, uniform scale deformation may be induced on the entire surface of the substrate W. This may be expressed as an equation, and the corresponding equation 3 may be expressed as follows.

$$Z = - \frac{{Mx}^{2}}{2 EI} \qquad [ Equation 3 ]$$

$$θ = \frac{dZ}{dx} = - \frac{M}{EI} x$$

$$Scale Error = \frac{t θ}{2} = \frac{t}{2} ( - \frac{M}{EI} x ) ∝ x$$

$$∴ Scale = \frac{t θ / 2}{x} = \frac{t}{2} ( - \frac{M}{EI} ) = Const .$$

In the above equation, θ denotes a curved angle of the wafer chuck WC and the substrate W. t denotes a thickness of the substrate W.

The moment bending mechanism may be realized in various ways. In the present disclosure, the following structure is provided as an example for actually implementing such a mechanism, especially for applying different moments between XY. The moment bending mechanism may be applied to the first stage 211 of the first bonding chuck 210, and may not be applied to the second stage 221 of the second bonding chuck 220. Alternatively, the moment bending mechanism may be applied to the second stage 221 of the second bonding chuck 220, and may not be applied to the first stage 211 of the first bonding chuck 210. Alternatively, the moment bending mechanism may be applied to both the first stage 211 of the first bonding chuck 210 and the second stage 221 of the second bonding chuck 220.

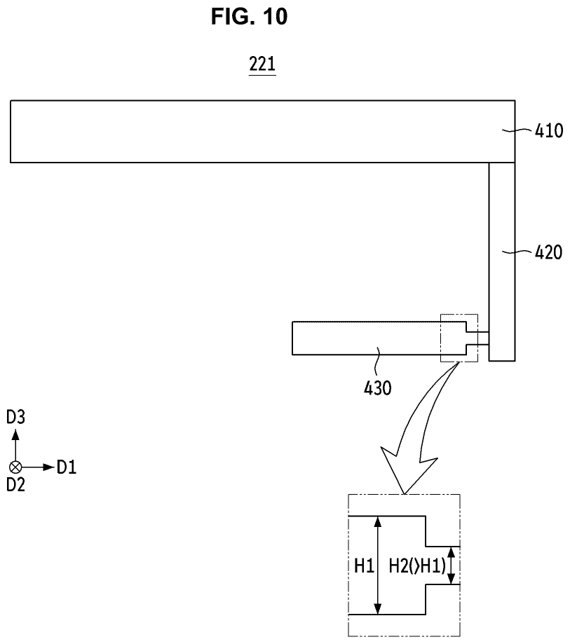

Hereinafter, a case that the moment bending mechanism is applied to the second stage 221 of the second bonding chuck 220 will be described as an example, but the present embodiment is not necessarily limited thereto. It is obvious that the moment bending mechanism described below may be equally applied to the first stage 211 of the first bonding chuck 210. FIG. 10 is a first exemplary view illustrating a structure of a second stage constituting a second bonding chuck according to some embodiments of the present disclosure.

Referring to FIG. 10, the second stage 221 may include a chucking member 410, a moment lever 420, and a flexure 430. The chucking member 410 may provide a seating surface to the second substrate W2. The chucking member 410 may adsorb and support the second substrate W2. The chucking member 410 may be provided as a flat plate. The chucking member 410 may be provided as a square shaped plane, but the present embodiment is not limited thereto. The plane of the chucking member 410 may be provided as a polygonal shape such as a triangle, a pentagon, and a hexagon, or a shape such as a circle or an ellipse. Hereinafter, a case that the chucking member 410 has a rectangular plane will be described as an example, but the present embodiment is not necessarily limited thereto.

The moment lever 420 may be coupled to the chucking member 410. The moment lever 420 may be coupled to a bottom surface of the chucking member 410. The moment lever 420 may be coupled to an edge portion of the chucking member 410. The moment lever 420 may be provided as a plurality of moment levers. Although not shown in FIG. 10, the plurality of moment levers 420 may be coupled to the edge portion of the chucking member 410 at regular intervals. Although not shown in FIG. 10, the plurality of moment levers 420 may be sequentially arranged to be spaced apart from each other in the second direction D2.

The flexure 430 may be coupled to the moment lever 420. The moment lever 420 may be coupled to the chucking member 410 and the flexure 430 through both ends thereof, respectively. The moment lever 420 may be simultaneously coupled to the chucking member 410 and the flexure 430. The moment lever 420 may be formed in the third direction D3 as a longitudinal direction. The flexure 430 may be formed in the first direction D1 as a longitudinal direction. The moment lever 420 may be extended in a direction different from that of the chucking member 410 as a longitudinal direction. The flexure 430 may be extended in the same direction as that of the chucking member 410 as a longitudinal direction. The moment lever 420 may be extended in a direction different from that of the flexure 430 as a longitudinal direction.

The flexure 430 may be provided to have a first thickness H1. However, an end portion of the flexure 430 coupled to the moment lever 420 may be provided to have a second thickness H2. The second thickness H2 may be provided as a value smaller than the first thickness H1. The flexure 430 may give a degree of freedom through a portion coupled to the moment lever 420 provided at the second thickness H2. The flexure 430 may apply only a pure moment to the moment lever 420 through the degree of freedom.

The flexure 430 may be provided as a plurality of flexures. The plurality of flexures 430 may be coupled to the plurality of moment levers 420. The flexures 430 may be coupled to the moment levers 420 in a one-to-one manner. The same number of flexures 430 as the number of moment levers 420 may be provided, but the present disclosure is not limited thereto. The flexure 430 may be coupled to the moment lever 420 in a one-to-multi manner. Alternatively, the flexure 430 may be coupled to the moment lever 420 in a multi-to-one manner. A different number of flexures 430 from the number of moment levers 420 may be provided. The moment lever 420 and the flexure 430 may be formed of a non-elastic material. The moment lever 420 and the flexure 430 may be formed of a rigid material.

Although not shown in FIG. 10, the moment lever 420 may be provided as a plurality of moment levers 420 at the edge portion of the chucking member 410 along each side of the chucking member 410. Hereinafter, structures of the moment lever 420 and the flexure 430 will be described in detail.

The moment lever 420 and the flexure 430 may be formed at edge portions of two sides facing each other. When sides of the chucking member 410 are defined as a first side, a second side, a third side, and a fourth side, respectively, the first side and the second side may correspond to two sides of the chucking member 410, which face each other. Alternatively, the third side and the fourth side may correspond to two sides of the chucking member 410, which face each other.

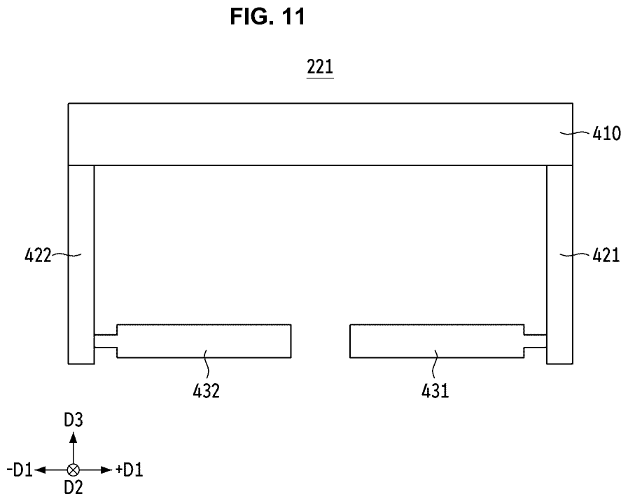

FIG. 11 is a second exemplary view illustrating a structure of a second stage constituting a second bonding chuck according to some embodiments of the present disclosure. Hereinafter, the first side and the second side of the chucking member 410 will be defined and described as two sides facing each other, but the present embodiment is not limited thereto, and may be equally applied to the third side and the fourth side of the chucking member 410.

Hereinafter, the moment lever and the flexure, which are installed on the first side, will be defined as a first moment lever 421 and a first flexure 431, respectively, for convenience of description. Furthermore, the moment lever and the flexure, which are installed on the second side, will be defined as a second moment lever 422 and a second flexure 432, respectively.

The first moment lever 421 and the first flexure 431 may be provided as a plurality of first moment levers and a plurality of first flexures. When the first moment lever 421 and the first flexure 431 are provided as a plurality of first moment levers and a plurality of first flexures, they may be spaced apart from each other in the second direction D2 and sequentially arranged.

The second moment lever 422 and the second flexure 432 may be provided as a plurality of second moment levers and a plurality of second flexures. When the second moment lever 422 and the second flexure 432 are provided as a plurality of second moment levers and a plurality of second flexures, they may be spaced apart from each other in the second direction D2 and sequentially arranged. The plurality of second moment levers 422 and the plurality of second flexures 432 may be provided in the same number as the first moment levers 421 and the first flexures 431. A distance between two adjacent second moment levers 422 may be equal to a distance between two adjacent first moment levers 421. However, the present disclosure is not limited to the above example, and the numbers of the second moment levers 422 and the second flexures 432 may be different from the numbers of the first moment levers 421 and the first flexures 431. The distance between two adjacent second moment levers 422 may be different from the distance between two adjacent first moment levers 421.

The first moment lever 421 and the second moment lever 422 may be formed in the third direction D3 as a longitudinal direction. The first moment lever 421 and the second moment lever 422 may be formed in the same direction as a longitudinal direction. The first flexure 431 and the second flexure 432 may be formed in the first direction D1 as a longitudinal direction. Lengths of the first flexure 431 and the second flexure 432 may be extended inward. The length of the first flexure 431 may be extended in a direction −D1. The length of the second flexure 432 may be extended in a direction +D1. The length extending direction of the first flexure 431 may be opposite to the length extending direction of the second flexure 432.

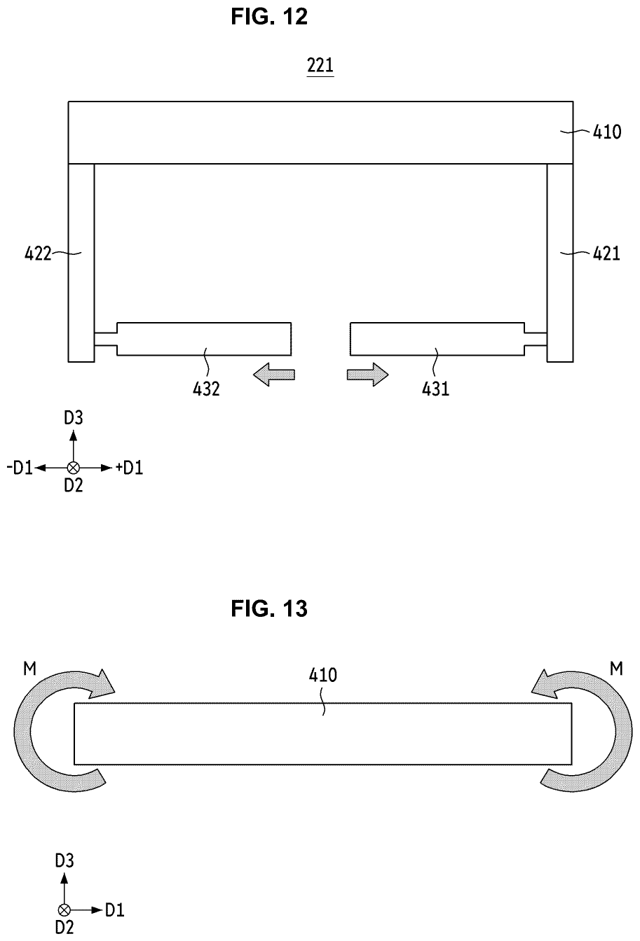

FIG. 12 is a first exemplary view illustrating a moment applied to a second stage according to some embodiments of the present disclosure. FIG. 13 is a second exemplary view illustrating a moment applied to a second stage according to some embodiments of the present disclosure. Referring to FIG. 12, a force may act on the first flexure 431 in the direction +D1. A force may act on the second flexure 432 in the direction −D1. A magnitude of the force acting on the first flexure 431 may be equal to a magnitude of the force acting on the second flexure 432. A direction of the force acting on the first flexure 431 may be different from a direction of the force acting on the second flexure 432. The direction of the force acting on the first flexure 431 may be opposite to the direction of the force acting on the second flexure 432.

Referring to FIGS. 12 and 13, when the force acts on the first flexure 431 in the direction +D1, a pushing force may be applied to the first moment lever 421. Likewise, when the force acts on the second flexure 432 in the direction −D1, the pushing force may be also applied to the second moment lever 422. A moment related to the pushing forces may be applied to each of the first moment lever 421 and the second moment lever 422 depending on degrees of freedom of the first flexure 431 and the second flexure 432. A moment M may be applied to the first side and the second side of the bottom surface of the chucking member 410 in a direction from a lower surface toward an upper surface.

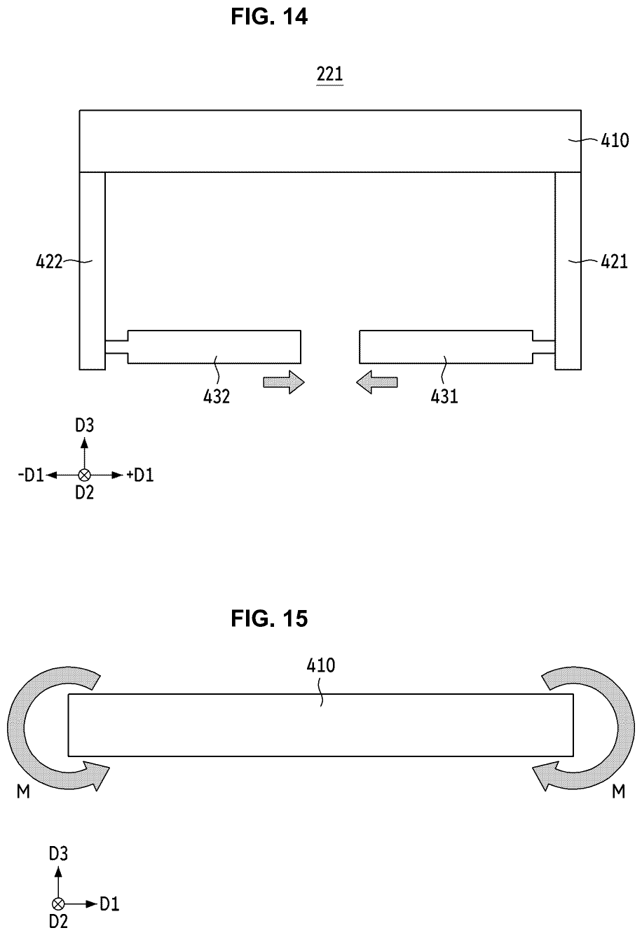

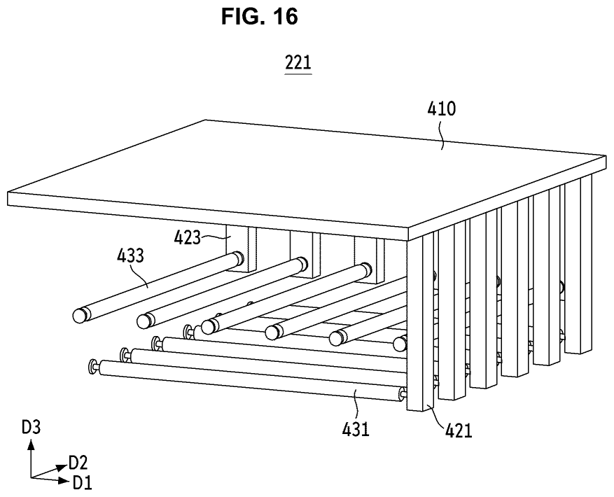

FIG. 14 is a third exemplary view illustrating a moment applied to a second stage according to some embodiments of the present disclosure. FIG. 15 is a fourth exemplary view illustrating a moment applied to a second stage according to some embodiments of the present disclosure. Referring to FIG. 14, a force may act on the first flexure 431 in the direction −D1. A force may act on the second flexure 432 in the direction +D1. A magnitude of the force acting on the first flexure 431 may be equal to a magnitude of the force acting on the second flexure 432. A direction of the force acting on the first flexure 431 may be different from a direction of the force acting on the second flexure 432. The direction of the force acting on the first flexure 431 may be opposite to the direction of the force acting on the second flexure 432.

Referring to FIGS. 14 and 15, when the force acts on the first flexure 431 in the direction −D1, a pulling force may be applied to the first moment lever 421. Likewise, when the force acts on the second flexure 432 in the direction +D1, the pulling force may be also applied to the second moment lever 422. A moment related to the pulling forces may be applied to each of the first moment lever 421 and the second moment lever 422 depending on the degrees of freedom of the first flexure 431 and the second flexure 432. A moment M may be applied to the first side and the second side of the bottom surface of the chucking member 410 in a direction from the upper surface toward the lower surface.

The moment lever 420 and the flexure 430 may be formed at edge portions of two adjacent sides. When sides of the chucking member 410 are defined as a first side, a second side, a third side, and a fourth side, respectively, the first side and the third side may correspond to two sides of the chucking member 410, which face each other. Alternatively, the first side and the fourth side may correspond to two sides of the chucking member 410, which face each other. Alternatively, the second side and the fourth side may correspond to two sides of the chucking member 410, which face each other.

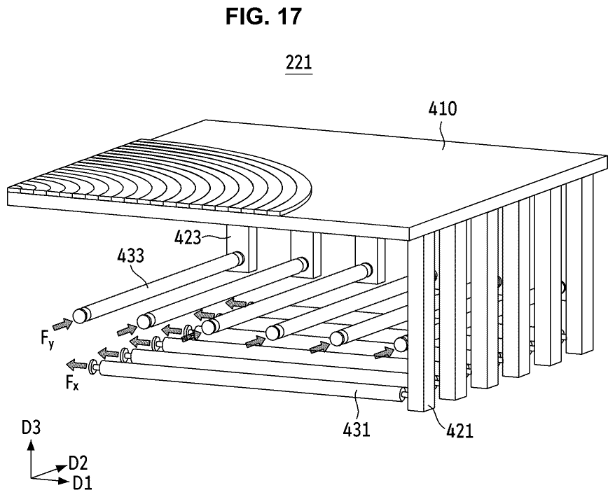

FIG. 16 is a third exemplary view illustrating a structure of a second stage constituting a second bonding chuck according to some embodiments of the present disclosure. Hereinafter, the first side and the third side of the chucking member 410 will be defined and described as two adjacent sides, but the present embodiment is not limited thereto, and may be equally applied to the first and fourth sides, the second and third sides, and the second and fourth sides of the chucking member 410.

Hereinafter, for convenience of description, the moment lever and the flexure, which are installed on the first side, will be defined as a first moment lever 421 and a first flexure 431, respectively. Furthermore, the moment lever and the flexure, which are installed on the third side, will be defined as a third moment lever 423 and a third flexure 433, respectively.

The first moment lever 421 and the first flexure 431 may be provided as a plurality of first moment levers and a plurality of first flexures. When the first moment lever 421 and the first flexure 431 are provided as a plurality of first moment levers and a plurality of first flexures, they may be spaced apart from each other in the second direction D2 and sequentially arranged.

The third moment lever 423 and the second flexure 433 may be provided as a plurality of second moment levers and a plurality of second flexures. When the third moment lever 423 and the third flexure 433 are provided as a plurality of third moment levers and a plurality of third flexures, they may be spaced apart from each other in the first direction D1 and sequentially arranged. The plurality of third moment levers 423 and the plurality of second flexures 433 may be provided in the same number as the first moment levers 421 and the first flexures 431. A distance between two adjacent third moment levers 423 may be equal to a distance between two adjacent first moment levers 421. However, the present disclosure is not limited to the above example, and the numbers of the third moment levers 423 and the third flexures 433 may be different from the numbers of the first moment levers 421 and the first flexures 431. The distance between two adjacent third moment levers 423 may be different from the distance between two adjacent first moment levers 421.

The first moment lever 421 and the third moment lever 423 may be formed in the third direction D3 as a longitudinal direction. The first moment lever 421 and the third moment lever 423 may be formed in the same direction as a longitudinal direction. Lengths of the first flexure 431 and the third flexure 433 may be extended inward. The first flexure 431 may be formed in the first direction D1 as a longitudinal direction. The third flexure 433 may be formed in the second direction D2 as a longitudinal direction. The length extending direction of the first flexure 431 may be orthogonal to the length extending direction of the third flexure 433.

Referring to FIG. 12, the first flexure 431 may be provided at the same level as the second flexure 432. A distance from the bottom surface of the chucking member 410 to the first flexure 431 may be equal to a distance from the bottom surface of the chucking member 410 to the second flexure 432. The lengths of the first flexure 431 and the second flexure 432 are extended inward, but may not meet each other.

On the other hand, referring to FIG. 16, the first flexure 431 may be provided at a different level from the third flexure 433. The distance from the bottom surface of the chucking member 410 to the first flexure 431 may be different from the distance from the bottom surface of the chucking member 410 to the third flexure 433. The distance from the bottom surface of the chucking member 410 to the first flexure 431 may have a value greater than the distance from the bottom surface of the chucking member 410 to the third flexure 433, but the present disclosure is not limited thereto. The distance from the bottom surface of the chucking member 410 to the first flexure 431 may have a value smaller than the distance from the bottom surface of the chucking member 410 to the third flexure 433.

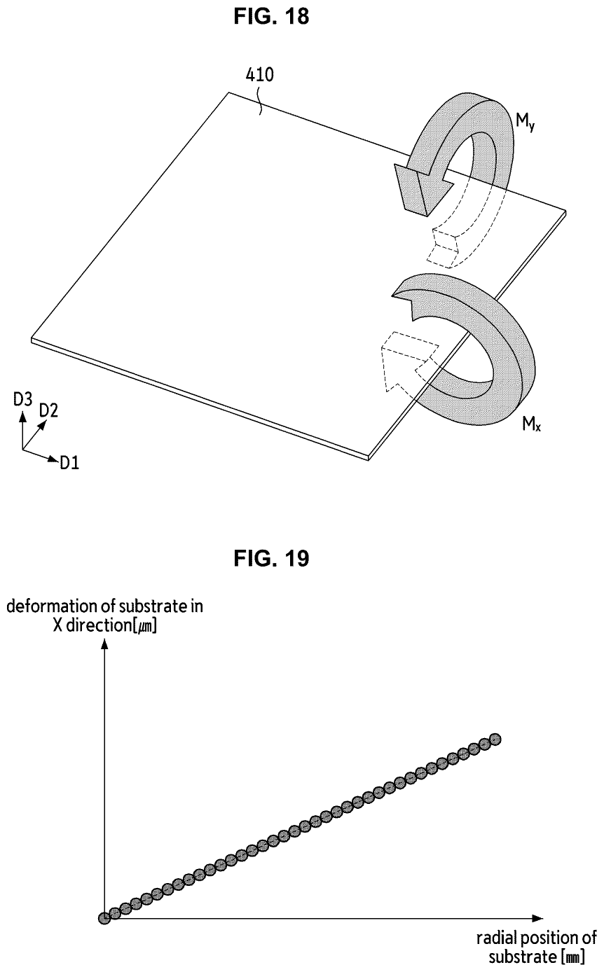

FIG. 17 is a fifth exemplary view illustrating a moment applied to a second stage according to some embodiments of the present disclosure. FIG. 18 is a sixth exemplary view illustrating a moment applied to a second stage according to some embodiments of the present disclosure. Different types of forces may be act on the first flexure 431 and the third flexure 433. Referring to FIG. 17, an pulling force may act on the first and third flexures 431, and a pushing force may act on the third flexure 433, but the present disclosure is not limited thereto. The pushing force may act on the first flexure, and the pulling force may act on the third flexure 433. An equivalent type of force may act on the first flexure 431 and the third flexure 433. For example, the pulling force may act on each of the first and third flexures 431 and 433. Alternatively, the pushing force may act on each of the first and third flexures 431 and 433.

A magnitude Fx of the force acting on the first flexure 431 may be equal to a magnitude Fy of the force acting on the third flexure 433, but the present disclosure is not limited thereto. The magnitude Fx of the force acting on the first flexure 431 may be different from the magnitude Fy of the force acting on the third flexure 433. The magnitude Fx of the force acting on the first flexure 431 and the magnitude Fy of the force acting on the third flexure 433 may be determined depending on a pattern scale formed in the cell wafer. The magnitude Fx of the force acting on the first flexure 431 and the magnitude Fy of the force acting on the third flexure 433 may be determined depending on warpage generated in the cell wafer. The magnitude Fx of the force acting on the first flexure 431 and the magnitude Fy of the force acting on the third flexure 433 may be equal to or different from each other depending on a determining factor thereof.

Likewise, a direction of the force acting on the first flexure 431 and a direction of the force acting on the third flexure 433 may be determined depending on the pattern scale formed in the cell wafer. The direction of the force acting on the first flexure 431 and the direction of the force acting on the third flexure 433 may be determined depending on warpage generated in the cell wafer. The direction of the force acting on the first flexure 431 and the direction of the force acting on the third flexure 433 may be equal to or different from each other depending on a determining factor thereof.

Referring to FIGS. 17 and 18, when the pulling force acts on the first flexure 431, a pure moment related to the pulling force may be applied to the first moment lever 421 depending on the degree of freedom of the first flexure 431. Also, when the pushing force acts on the third flexure 433, a pure moment related to the pushing force may be applied to the third moment lever 423 depending on the degree of freedom of the third flexure 433. In accordance with the moment applied to the first moment lever 421, a moment Mx may be applied to the first side of the bottom surface of the chucking member 410 in a direction from an upper surface toward a lower surface. In accordance with the moment applied to the third moment lever 423, a moment My may be applied to the third side of the bottom surface of the chucking member 410 in a direction from the lower surface toward the upper surface.

The wafer chuck has a rectangular shape, and may have a size larger than that of the substrate. The plurality of moment levers 420 may be attached to each corner of the wafer chuck, and the flexure 430 may be attached to an opposite end below the corresponding moment lever 420. By pushing or pulling the end below the moment lever 420 by the same force through the structure of the flexure 430, a certain moment may be induced at the end of the wafer chuck. Particularly, since the flexure 430 has a degree of freedom in a direction other than a force for pushing or pulling the moment lever 420 due to its structural characteristics, only a pure moment may be applied to the end of the wafer chuck. Furthermore, when the moment lever 421 of an X direction corner and the moment lever 423 of a Y direction corner are pushed or pulled by different forces Fx and Fy, respectively, different moments Mx and My may be applied in the XY direction, respectively.

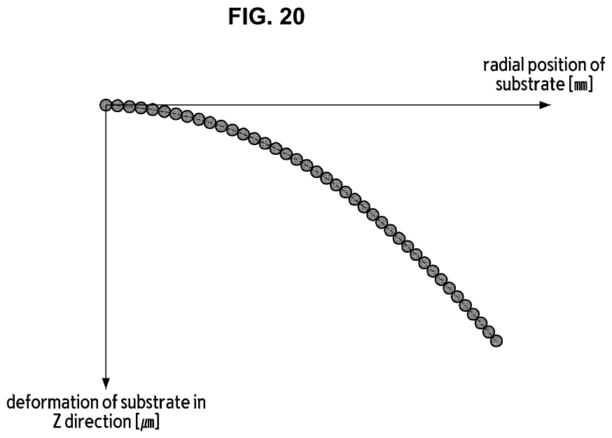

FIG. 19 is a first exemplary view illustrating a verification result of a moment bending mechanism according to some embodiments of the present disclosure. FIG. 20 is a second exemplary view illustrating a verification result of a moment bending mechanism according to some embodiments of the present disclosure.

In order to verify the moment bending mechanism, when an attraction force with a first magnitude is given to the first flexure 431 and an attraction with a second magnitude different from the first magnitude is given to the third flexure 433, a displacement of the substrate in the first direction D1 may be expressed as a graph of FIG. 19, and a displacement of the substrate in the third direction D3 may be expressed as a graph of FIG. 20.

First, referring to FIG. 19, it may be seen that a displacement of the substrate in the X direction D1 follows a shape of a primary straight line depending on a radial position of the substrate. As a result, it may be confirmed that deformation conforming to the definition of scale on the substrate, that is, uniform scale deformation on the entire surface of the substrate may be induced through the moment bending mechanism.

Next, referring to FIG. 20, it may be seen that a displacement of the chuck in the Z-direction D3 follows a shape of a secondary curve depending on the radial position of the substrate. As a result, it may be confirmed that an intended secondary deform shape may be induced by applying a pure moment to the end of the chucking member 410 through the moment bending mechanism.

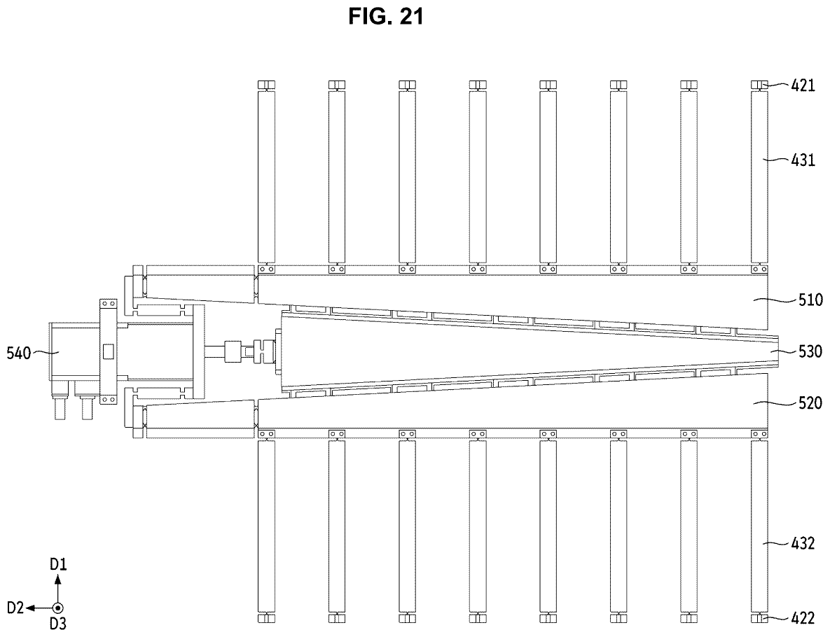

Next, the wedge mechanism will be described subsequently to the moment lever mechanism of the moment bending mechanism. FIG. 21 is a fourth exemplary view illustrating a structure of a second stage constituting a second bonding chuck according to some embodiments of the present disclosure. Referring to FIG. 21, the second stage 221 may further include a first wedge 510, a second wedge 520, a third wedge 530, and a wedge controller 540.

The first wedge 510 may be coupled to the first flexure 431. The first flexure 431 may be provided as a plurality of first flexures. The first wedge 510 may be coupled to the plurality of first flexures 431. A length of the first wedge 510 may be extended in a direction in which the plurality of first flexures 431 are arranged. The first wedge 510 may be formed in the second direction D2 as a longitudinal direction. Each of the first flexures 431 may be coupled to each of the first moment levers 421.

The second wedge 520 may be coupled to the second flexure 432. The second flexure 432 may be provided as a plurality of second flexures. The second wedge 520 may be coupled to the plurality of second flexures 432. A length of the second wedge 520 may be extended in a direction in which the plurality of second flexures 432 are arranged. The second wedge 520 may be formed in the second direction D2 as a longitudinal direction. Each of the second flexures 432 may be coupled to each of the second moment levers 422.

The first flexure 431 and the second flexure 432 may not meet. The first wedge 510 and the second wedge 520 may be arranged in a space between the first flexure 431 and the second flexure 432. The first wedge 510 may be located inside the first flexure 431. The second wedge 520 may be located inside the second flexure 432. The first wedge 510 may be adjacent to the second wedge 520. The first wedge 510 may not be in contact with the second wedge 520. The third wedge 530 may be arranged between the first wedge 510 and the second wedge 520.

The first wedge 510 may be coupled to the plurality of first flexures 431 through one surface thereof. The other surface of the first wedge 510 may face the second wedge 520. The other surface of the first wedge 510 may be formed to be inclined in the second direction D2. An inclination angle of the other surface of the first wedge 510 may be greater than 0° and less than 90°.

The second wedge 520 may be coupled to the plurality of second flexures 432 through one surface thereof. The other surface of the second wedge 520 may face the first wedge 510. The other surface of the second wedge 520 may be formed to be inclined in the second direction D2. An inclination angle of the other surface of the second wedge 520 may be greater than 0° and less than 90°.

The inclination angle of the second wedge 520 may be equal to the inclination angle of the first wedge 510. However, an inclination direction of the second wedge 520 may be different from an inclination direction of the first wedge 510. The inclination direction of the second wedge 520 may be opposite to the inclination direction of the first wedge 510. The inclination direction of the second wedge 520 may be the same as the inclination direction of the first wedge 510 when the second wedge 520 is rotated by 180° in the first direction D1.

The third wedge 530 may be arranged between the first wedge 510 and the second wedge 520. The third wedge 530 may be formed of a material equivalent to that of the first wedge 510 and the second wedge 520. The first wedge 510, the second wedge 520 and the third wedge 530 may be formed of a non-elastic material. The first wedge 510, the second wedge 520 and the third wedge 530 may be formed of a rigid material.

The third wedge 530 may be in contact with the first wedge 510. A portion of the third wedge 530, which is in contact with the first wedge 510, may be formed to be inclined. When a portion of the first wedge 510, which is in contact with the third wedge 530, is defined as a first portion of the first wedge 510 and a portion of the third wedge 530, which is in contact with the first wedge 510, is defined as a first portion of the third wedge 530, the first portion of the third wedge 530 may have the same inclination angle as that of the first portion of the first wedge 510. The first portion of the third wedge 530 may have a different inclination direction from the first portion of the first wedge 510. The first portion of the third wedge 530 may be inclined in a direction opposite to the first portion of the first wedge 510.

The third wedge 530 may be also in contact with the second wedge 520. A portion of the third wedge 530, which is in contact with the second wedge 520, may be formed to be inclined. When a portion of the second wedge 520, which is in contact with the third wedge 530, is defined as a first portion of the second wedge 520, and a portion of the third wedge 530, which is in contact with the second wedge 520, is defined as a second portion of the third wedge 530, the second portion of the third wedge 530 may have the same inclination angle as that of the first portion of the second wedge 520. The second portion of the third wedge 530 may have a different inclination direction from the first portion of the second wedge 520. The second portion of the third wedge 530 may be formed to be inclined in a direction opposite to the first portion of the second wedge 520.

The third wedge 530 may move in the second direction D2 under the control of the wedge controller 540. The first portion of the first wedge 510 and the first portion of the third wedge 530 may be formed in a structure that may minimize a frictional force. For example, a member capable of reducing a frictional force may be arranged between the first portion of the first wedge 510 and the first portion of the third wedge 530. For example, a linear motion (LM) guide capable of moving the third wedge 530 may be installed in the first portion of the first wedge 510 and the first portion of the third wedge 530.

Likewise, the first portion of the second wedge 520 and the second portion of the third wedge 530 may be also formed in a structure capable of minimizing a frictional force. For example, a member capable of reducing a frictional force may be arranged between the first portion of the second wedge 520 and the second portion of the third wedge 530. For example, an LM guide capable of moving the third wedge 530 may be installed in the first portion of the second wedge 520 and the second portion of the third wedge 530.

The wedge controller 540 may provide a dynamic power to the third wedge 530. The third wedge 530 may move in the second direction D2 under the control of the wedge controller 540. Although not shown in FIG. 21, the wedge controller 540 may include a motor and a power source.

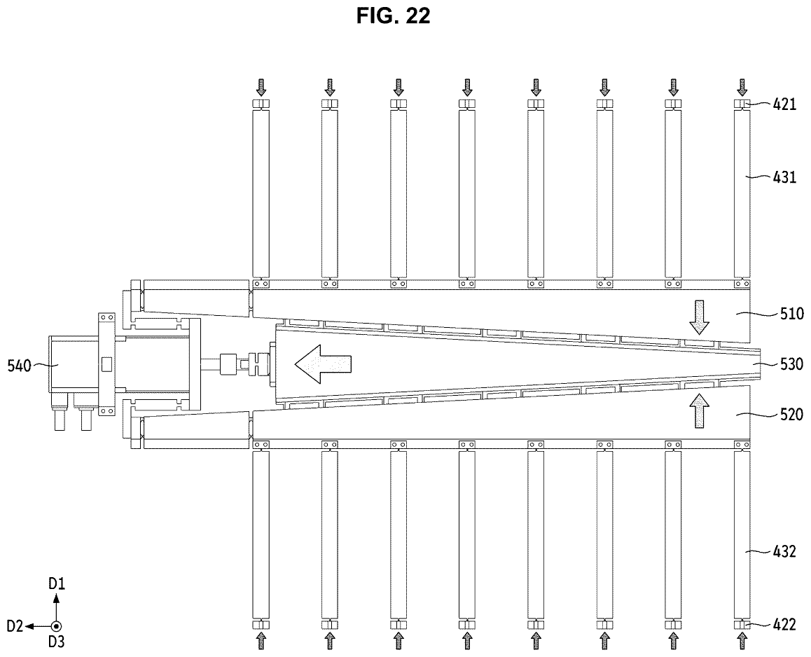

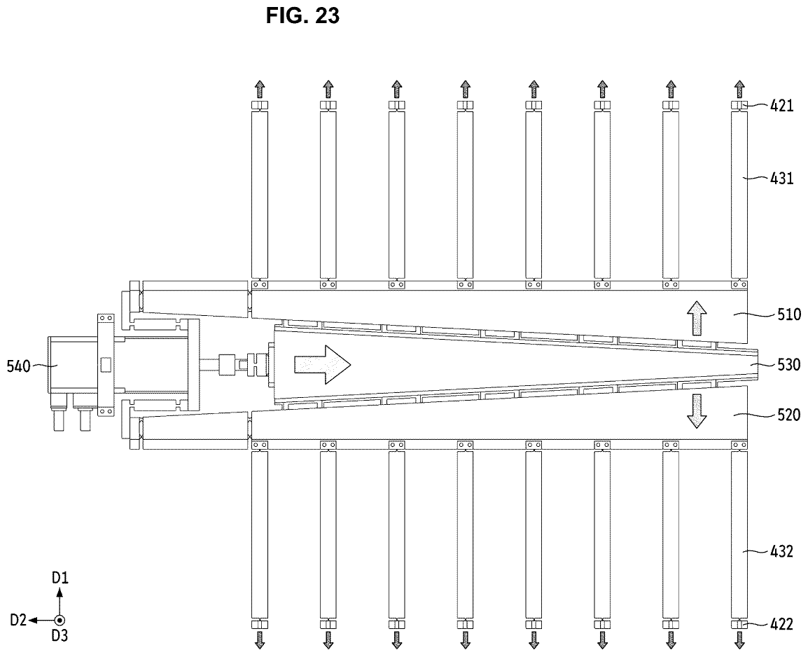

FIG. 22 is a seventh exemplary view illustrating a moment applied to a second stage according to some embodiments of the present disclosure. Referring to FIG. 22, the third wedge 530 may move in a left direction under the control of the wedge controller 540. When the third wedge 530 moves in the left direction, a force may act on the first wedge 510 and the second wedge 520 in a direction in which the third wedge 530 is located. An pulling force may act on each of the first and second flexures 431 and 432.

FIG. 23 is an eighth exemplary view illustrating a moment applied to a second stage according to some embodiments of the present disclosure. Referring to FIG. 23, the third wedge 530 may move in a right direction under the control of the wedge controller 540. When the third wedge 530 moves in the right direction, a force may act on the first wedge 510 and the second wedge 520 in a direction in which the first and second flexures 431 and 432 are located. A pushing force may act on each of the first and second flexures 431 and 432.

The wedge mechanism may realize an operation of pulling or pushing a plurality of moment levers 420, which are a core of moment bending, with the same force. For example, in order to apply a moment in the Y direction to the wafer chuck, it is necessary to pull a plurality of first moment levers 421 at a position +Y and a plurality of second moment levers 422 at a position −Y with the same force. To this end, each of the first moment levers 421 is coupled to the first wedge 510 through each of the first flexures 431, and each of the second moment levers 422 may be coupled to the second wedge 520 through each of the second flexures 432. The first flexure 431 and the second flexure 432 may have a degree of freedom in a direction other than a pushing or pulling force, thereby preventing unnecessary delivery of a force. Each of the first wedge 510 and the second wedge 520 may have a wedge shape in which opposite surfaces to which the first flexure 431 and the second flexure 432 are fixed are inclined in a shape of an oblique surface.

Also, the third wedge 530 having a certain inclination may be coupled between the first wedge 510 and the second wedge 520 so as to push or pull the first wedge 510 and the second wedge 520 in the Y direction by the same amount. Through the wedge mechanism, the first wedge 510 and the second wedge 520 may simultaneously move in the Y direction by the same amount only by a simple operation of pushing or pulling the third wedge 530 in the X direction, and the plurality of moment levers 421 and 422 and flexures 431 and 432, which are coupled thereto, may be also pushed or pulled by the same amount and force.

The present disclosure relates to a wafer chuck capable of performing asymmetric deformation based on a moment bending mechanism. The wafer chuck may be provided as the chucking member 410 in the first bonding chuck 210. The wafer chuck may be provided as the chucking member 410 in the second bonding chuck 220. The wafer chuck may be provided for asymmetric scale compensation in the wafer bonding process.

The wafer chuck is a deformation chuck, and may be formed in a structure that implements deformation by applying a moment to an end of the chuck. A shape of the wafer chuck may be provided in a rectangular shape so that the same or different moment may be applied in the X direction D1 and the Y direction D2. A moment may be applied to the end of each corner of the chuck, so that a uniform scale having a radial displacement proportional to the radial position of the substrate may be induced, and an asymmetric scale between XY may be induced when different moments are applied between XY.

The moment bending mechanism may be implemented in various structures, and a mechanism using a moment lever is provided in the present disclosure as an example. In the structure of the corresponding mechanism, a plurality of moment levers are attached to each corner of the wafer chuck, and a flexure structure is attached to the end below each lever, so that the moment lever may be pushed or pulled. In particular, since the flexure has a degree of freedom in a direction other than the force to push or pull the moment lever due to its structure characteristics, only a pure moment may be applied at the end of the chuck.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical concepts or characteristics of the present disclosure. Therefore, it should be appreciated that the embodiments as described above are not restrictive but illustrative in all respects.

What is claimed is:

1. A substrate treating apparatus comprising:
a first bonding chuck supporting a first substrate; and
a second bonding chuck facing the first bonding chuck and supporting a second substrate,
wherein the second bonding chuck includes a second stage fixing the second substrate, and
wherein the second stage is deformed based on a moment applied along an edge region thereof.

2. The substrate treating apparatus of claim 1, wherein the second bonding chuck includes:
a plurality of moment levers coupled to the second stage along the edge region of the second stage; and
a plurality of flexures individually coupled to the moment levers.

3. The substrate treating apparatus of claim 2, wherein a longitudinal direction of the moment levers is different from a longitudinal direction of the flexures.

4. The substrate treating apparatus of claim 3, wherein the moment is generated in the moment levers based on a force applied to the flexures.

5. The substrate treating apparatus of claim 2, wherein an end portion of the flexures coupled to the moment levers has a different thickness from other portions thereof.

6. The substrate treating apparatus of claim 2,
wherein the edge region includes a first portion and a second portion, and
wherein the first portion faces the second portion.

7. The substrate treating apparatus of claim 6, wherein a flexure connected to the first portion among the flexures is formed at a level equivalent to a flexure connected to the second portion among the flexures.

8. The substrate treating apparatus of claim 2,
wherein the edge region includes a first portion and a third portion, and
wherein the first portion is adjacent to the third portion.

9. The substrate treating apparatus of claim 8, wherein a flexure connected to the first portion among the flexures is formed at a different level from a flexure connected to the third portion among the flexures.

10. The substrate treating apparatus of claim 2,
wherein the edge region includes a plurality of portions, and
wherein the flexures connected to each portion has an applied force of which magnitude is determined depending on a pattern scale formed in the second substrate.

11. The substrate treating apparatus of claim 2,
wherein the edge region includes a plurality of portions, and
wherein the flexures connected to each portion has an applied force of which direction is determined depending on a pattern scale formed in the second substrate.

12. The substrate treating apparatus of claim 2,
wherein the edge region includes a plurality of portions, and
wherein the flexures connected to each portion has an applied force of which magnitude is determined depending on warpage generated in the second substrate.

13. The substrate treating apparatus of claim 2,
wherein the edge region includes a plurality of portions, and
wherein the flexures connected to each portion has an applied force of which direction is determined depending on warpage generated in the second substrate.

14. The substrate treating apparatus of claim 2, wherein the second bonding chuck includes:
a first wedge coupled to any one of the plurality of flexures;
a second wedge coupled to the other one of the plurality of flexures;
a third wedge located between the first wedge and the second wedge; and
a wedge controller giving mobility to the third wedge.

15. The substrate treating apparatus of claim 14, wherein the first wedge and the second wedge include an inclined surface.

16. The substrate treating apparatus of claim 15, wherein the third wedge includes a third inclined surface engaged with a first inclined surface of the first wedge and a fourth inclined surface engaged with a second inclined surface of the second wedge.

17. The substrate treating apparatus of claim 14, wherein a moving direction of the third wedge is different from a longitudinal direction of the flexure coupled to the first wedge.

18. The substrate treating apparatus of claim 14, wherein the third wedge has a width increased from a first direction to a second direction.

19. A substrate treating apparatus comprising:
a first bonding chuck supporting a first substrate; and
a second bonding chuck facing the first bonding chuck and supporting the second substrate,
wherein the second bonding chuck includes:
a second stage fixing the second substrate;
a plurality of moment levers coupled to the second stage along an edge region of the second stage; and
a plurality of flexures individually coupled to the moment levers,
wherein the edge region of the second stage includes a plurality of portions, and
wherein the second stage is symmetrically deformed based on a moment applied along each portion.

20. A substrate treating apparatus comprising:
a first bonding chuck supporting a first substrate; and
a second bonding chuck facing the first bonding chuck and supporting a second substrate,
wherein the second bonding chuck includes:
a second stage fixing the second substrate;
a plurality of moment levers coupled to the second stage along an edge region of the second stage; and
a plurality of flexures individually coupled to the moment levers,
wherein the edge region of the second stage includes a plurality of portions, and
wherein the second stage is asymmetrically deformed based on a pattern scale formed in the second substrate or a moment differentially applied depending on warpage generated in the second substrate.
